(19) United States
(12) Patent Application Publication
(10) Pub. No.: US 2011/0177623 A1
(43) Pub. Date: Jul. 21, 2011

(54) Active Tribology Management of CMP Polishing Material

(75) Inventors: Stephen J. Benner, Lansdale, PA (US); Darryl W. Peters, Stewartsville, NJ (US)

(73) Assignee: CONFLUENSE LLC, Allentown, PA (US)

(21) Appl. No.: 13/005,633

(22) Filed: Jan. 13, 2011

Related U.S. Application Data
(60) Provisional application No. 61/295,336, filed on Jan. 15, 2010.

(51) Int. Cl. H01L 21/66; B24B 55/00

(52) U.S. Cl. 438/5; 451/5; 257/E21.528

(57) ABSTRACT

An arrangement and method for managing the tribology associated with a chemical mechanical planarization (CMP) process continuously monitors and modifies the properties of a polishing slurry in order to assist in controlling the removal rate associated with the CMP process. The viscosity of slurry as it leaves the CMP system (“spent slurry”) and the material removal rate associated with the semiconductor wafer are measured, and then the viscosity of the incoming slurry is adjusted if the measured material removal rate differs from a desired removal rate. If the removal rate is considered to be too fast, the viscosity of the fresh slurry being dispensed onto polishing pad is decreased; alternatively, if the removal rate is too slow, the viscosity is increased. As an alternative to modifying the viscosity of the slurry (or, perhaps in addition to modifying the viscosity), a lubricant may be added to the slurry to slow down the removal rate.

### CROSS-REFERENCE TO RELATED APPLICATIONS

This application claims the benefit of U.S. Provisional Application No. 61/295,336, filed Jan. 15, 2010 and hereby incorporated by reference.

### TECHNICAL FIELD

The present invention is related an arrangement and method for managing the tribology associated with a chemical mechanical planarization (CMP) process and, more particularly, to a method for continuously monitoring and modifying the properties of a polishing slurry in order to assist in controlling the removal rate associated with the CMP process.

### BACKGROUND OF THE INVENTION

A process known in the art as Chemical Mechanical Planarization (CMP), including electro-CMP (eCMP), has evolved as a preferred technique for planarizing a semiconductor wafer surface. In a conventional CMP process, the semiconductor wafer is mounted on a rotating plate or other holder, with the non-planar surface of the wafer brought into contact with a polishing surface of a polishing pad. The irregular topology of the non-planar surface (attributed to prior processing of the wafer, underlying layers, patterns, etc.) is removed by creating relative motion between the wafer and the polishing pad, while providing a supply of one or more slurry compositions to the surface of the polishing pad. Depending on the materials being removed, a CMP process may be primarily mechanical (material removal dominated by abrasive action), chemical (material removal dominated by etching of the surface material), or as is more often the case, a combination of both mechanical and chemical processes. As a result of the inherent instability of the interfacial layer (boundary layer) at the polishing pad surface, a pad conditioning operation has been widely adopted in the CMP industry to reduce variations in the removal rate of the semiconductor wafer surface.

FIG. 1 depicts, in simplified form, a semiconductor wafer 1 having an irregular surface 2, where irregular surface 2 is positioned over a polishing pad 3. A polishing slurry 4 containing both a liquid constituent 5 and abrasive particles 6 is shown as disposed between wafer 1 and polishing pad 3, and is used to assist in the planarization process.

In order to understand the various forces at work in the CMP process, the tribology of the complete system should be evaluated and understood. The term “tribology” has come to refer to the branch of engineering associated with friction, wear and lubrication, and is often defined as the “science of interacting surfaces moving relative to each other”. In this science, one useful tool is a Stribeck curve, which expresses the relationship between the coefficient of friction, viscosity of the lubricating material, load and velocity.

When applying the science of tribology to the particulars of a CMP process, the CMP process should be designed to operate in the ‘elasto-hydrodynamic lubrication’ regime of the Stribeck curve (see FIG. 2), where chemical action on irregular wafer surface 2 (caused by one or more liquid constituents 5 of polishing slurry 4) functions to “soften” the surface and allow it to be abraded away by “incidental”, occasional, or what is sometimes referred to as “stick-slip” mechanical contact between one or more of the solid materials involved in the process (i.e., slurry abrasive particles 6, wafer surface solids, pad solids), driven by the mechanical actions of the polisher (e.g., rotation, downforce).

The Stribeck curve as shown in FIG. 2 plots the coefficient of friction (CoF) between two surfaces (in this case, pad 3 and wafer 1) separated by a thin film of fluid (in this case, polishing slurry 4) against the Hersey number (also referred to as the Sommerfeld number), which is a function of pressure, velocity and viscosity of the film (polishing slurry). This three-body abrasion (workpiece, interfacial materials (liquids and solid) and pad (normal force component for friction)) has been a topic of much tribological research. Control of the removal rate requires adjustment of the parameters affecting the tribology (friction, lubrication, wear) so as to compensate or predictively modify the removal process.

For any particular slurry and pad composition, as well as the equipment parameters under which the CMP process is conducted, the materials act on the wafer relative to the particular characteristics of the various primary and secondary materials to be removed from the substrate surface. For example, in a case where a polysilicon layer and a composite, patterned silicon oxide layer are being polished using a silica-based slurry having SiO₂ as the primary abrasive, the removal rate of the polysilicon will tend to be higher than the removal rate of silicon oxide. These composite structures each have differing responses to the process inputs, yet planarization requires the CMP process to end with no vestiges remaining of the prior processes.

Stabilizing and/or controlling the local CoF at the wafer surface and associated removal characteristics of single or composite structures requires discrete control of one or more of the following system parameters: the composition, concentration and morphology of the solids in the slurry; the liquid film attributes of the slurry (e.g., temperature, viscosity, chemistry, thickness); energy/work attributes of the CMP system (downforce, speed, temperature, the tool geometry itself (which generates shear and normal components)); and the parameters associated with the polishing pad (mechanical properties, surface topography, bearing/contact area, etc.). The prior art allows for the measurement and control of only some of these three-body tribological attributes.

### SUMMARY OF THE INVENTION

The needs remaining in the prior art are addressed by the present invention, which is related to an arrangement and method for managing the tribology associated with a chemical mechanical planarization (CMP) process and, more particularly, to a method for continuously monitoring and modifying the properties of a polishing slurry in order to assist in controlling the removal rate associated with the CMP process.

The present invention is directed to controlling the effective viscosity of the slurry, as well as the material removal rate associated with the semiconductor wafer, and then adjusting the slurry's viscosity (and/or, perhaps its lubricity) in real time (i.e., on-the-fly) to control the material removal rate on the wafer surface.

In accordance with the present invention, used slurry is continuously removed from CMP equipment during a planarization process, where the slurry is one component of the effluent which also includes conditioning materials, abraded particles removed from the wafer, and the like (collectively referred to as “effluent”). The constituents of the slurry are separated the remainder of the effluent and the viscosity of the slurry is measured and associated with the current removal rate. If the removal rate is considered to be too fast, the viscosity of the fresh slurry being dispensed onto polishing pad is decreased; alternatively, if the removal rate is too slow, the viscosity is increased. As an alternative to modifying the viscosity of the slurry (or, perhaps in addition to modifying the viscosity), a lubricant may be added to the slurry to slow down the removal rate.

Chemically-neutral additives are utilized in accordance with the present invention to either increase or decrease the viscosity of the polishing slurry, or as a lubricating additive. For example, soluble starch solution, sucrose solution, or various high molecular weight polymers maybe used to increase the slurry's viscosity, with components such as non-reactive, water soluble, low viscosity solvents (e.g., 2-butanone, cyclopentanol) used in accordance with the present invention to decrease the slurry's viscosity. Solid materials such as graphite, or liquids such as fatty acids, may be used as lubricants to slow the material removal rate (i.e., to act as a “breaking force” in the planarization process).

Other and further attributes of the present invention will become apparent during the course of the following discussion and by reference to the accompanying drawings.

### BRIEF DESCRIPTION OF THE DRAWINGS

Referring now to the drawings,

FIG. 1 is a diagram of a portion of a CMP system, illustrating the three-body tribology associated with the planarization process;

FIG. 2 is a Stribeck curve illustrating the factors associated with viscosity;

FIG. 3 is a fishbone diagram outlining the different groupings of factors that influence a CMP process;

FIG. 4 is a diagram of the parameters associated with viscosity; and

FIG. 5 is a CMP system including a feedback path for controlling viscosity/lubricity of incoming polishing slurry in accordance with the present invention.

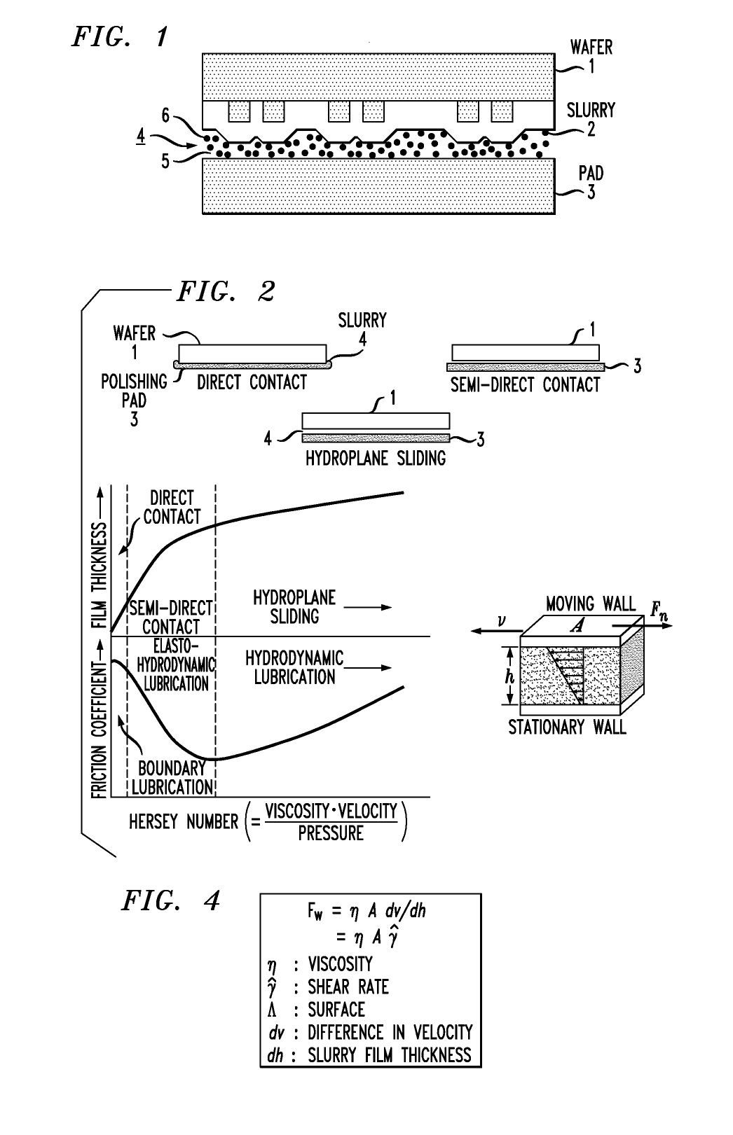

### DESCRIPTION OF THE INVENTION

As mentioned above, the overall control of the CMP process is difficult in light of the many parameters that affect film removal. FIG. 3 is a “fishbone” diagram that illustrates these parameters, including those associated with physical qualities of the polishing pad (denoted as group A in FIG. 3), the conditioning material (group B) and the abrasive material (group C). Also impacting the CMP process is the CMP equipment parameters (group D), the specifics of the semiconductor wafer being worked (group E) and the chemistry of the slurry (group F). The present invention addresses this last aspect—the slurry itself—and, more particularly, the viscosity and lubricity of the slurry.

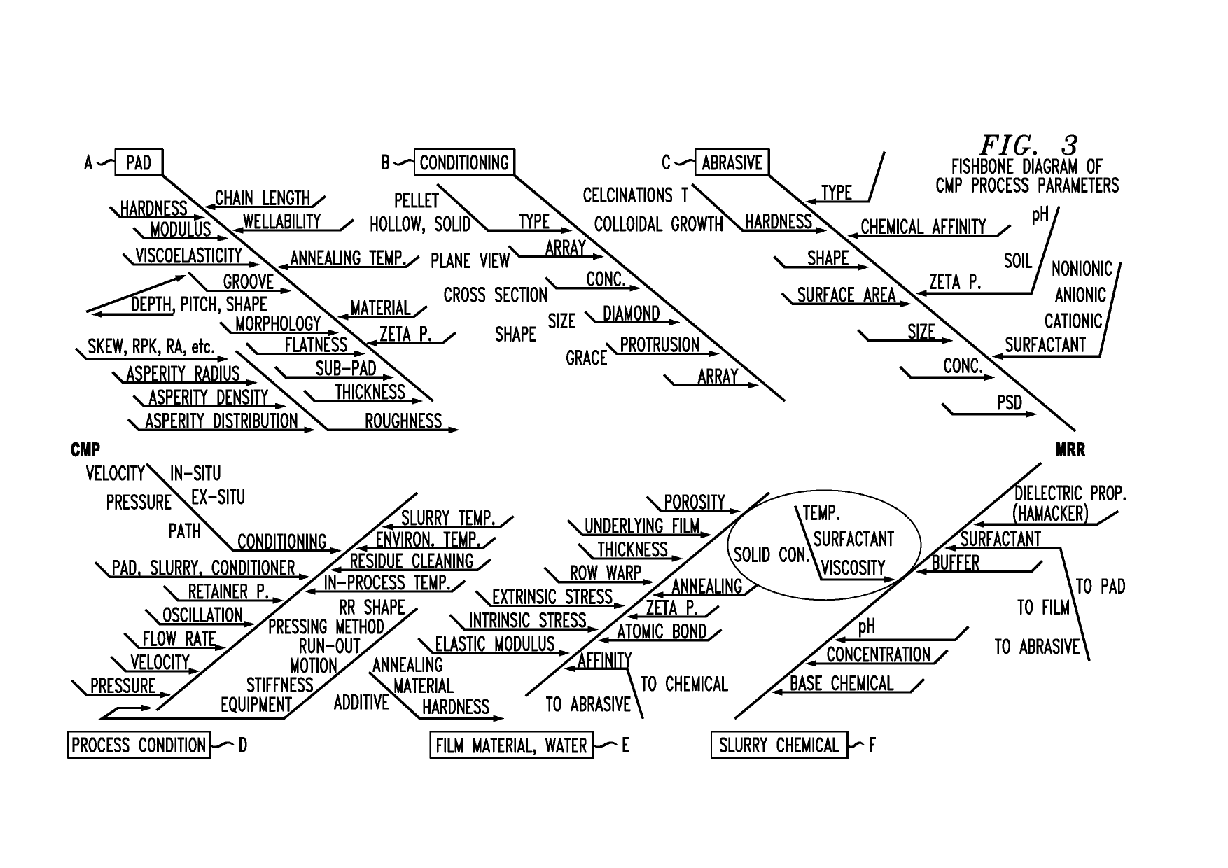

The viscosity of a polishing slurry is one of many attributes that is characterized by a slurry manufacturer. Viscosity is a material-dependent correlation factor that describes the amount of force (F_{w}) necessary to move a surface area on a slurry film of a certain thickness at a desired velocity, as shown in FIG. 4. Viscosity can be measured in units of centipoise (cP), where water at 20° C. is defined as having a viscosity of 1.002 cP. Typically, a slurry is mixed in bulk by combining abrasive particles and additives, oxidizers, etchants and/or de-ionized water with a suspension agent.

The lubricity of the polishing slurry is generally thought of as a measure of the reduction in friction of the slurry, describing the ability of the slurry to reduce friction between the polishing pad and the wafer. In a CMP system, a lubricant may be included in the polishing slurry, in the form of a solid (e.g., graphite) suspended in the liquid or an additional liquid component (such as a fatty acid or non-reactive surfactant chemical). The addition of a lubricant, in this system, will function to decelerate the planarization process.

The present invention is directed to monitoring the viscosity of the slurry, as well as the material removal rate, and then adjusting the slurry's viscosity (and/or lubricity) in real time (i.e., on-the-fly) to control the material removal rate.

The need to monitor and adjust the viscosity is important for many reasons, not the least of which being the possibility for the “as manufactured” viscosity to change by the time the actual slurry material is used in a CMP system. Various factors will affect the viscosity, including the age of the material, the ‘shelf life’ of the material, environmental factors to which the material has been subjected, and the like. Thus, the actual viscosity of the dispensing slurry may be different from that which the user believes it to exhibit, based upon the specifications of the purchased slurry material.

In accordance with the present invention, only the viscosity and/or lubricity of the polishing slurry is manipulated. Non-reactive, water soluble, high viscosity materials are used to increase the slurry viscosity (e.g., soluble starch solution, sucrose solution, high molecular weight polymers, ethanolamine, diethanolamine, triethanolamine, or other non-reactive water soluble solvents or mixtures thereof with a viscosity substantially greater than that of deionized water (about 1 cP near room temperature)). Non-reactive, water soluble, low viscosity solvents or lubricants are used in accordance with the present invention to decrease the slurry's viscosity (or lubricity), where materials such as 2-butanone, cyclopentanol, or any other non-reactive water soluble solvent or mixture thereof with a viscosity substantially less than that of deionized water may be used to adjust the viscosity and materials such as graphite, fatty acids, or the like used as friction-reducing lubricants.

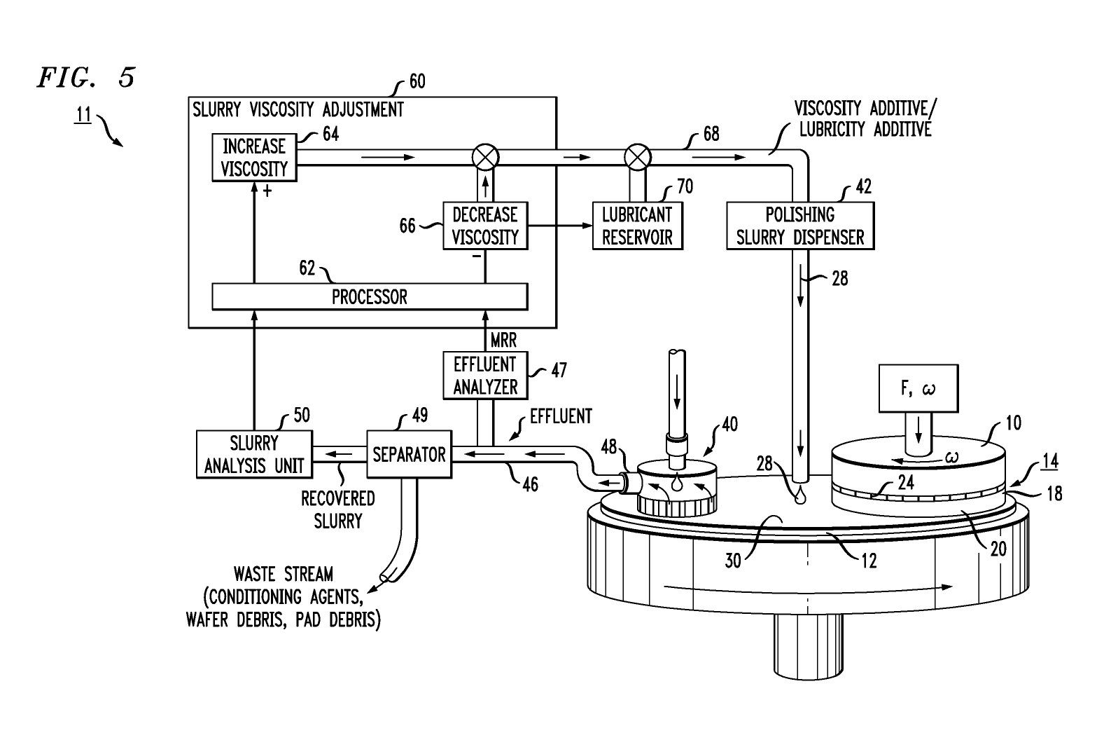

FIG. 5 illustrates an exemplary apparatus that may be used to monitor both the viscosity of the processed slurry and the removal rate of the material being polished, and thereafter modify the viscosity and/or lubricity of the slurry in order to control the material removal rate. As shown, a polishing head 10 is positioned above a polishing pad 12 of a CMP system 11. A semiconductor wafer 14 is attached to the bottom surface of polishing head 10 and is thereafter lowered onto polishing pad 12 (which is a rotating pad in this configuration) to initiate the planarization process. In this example, semiconductor wafer 14 is shown as comprising a thick layer 18 that may be, for example, a dielectric material or a metal (such as copper). Indeed, “layer 18” may comprise a stack of layers of different materials—dielectrics, metals, “barrier layers”, trench linings, and the like.

A polishing slurry dispenser 42 is used to introduce a polishing slurry 28 of a predetermined composition (including initial viscosity and lubricity) onto surface 30 of polishing pad 12, where polishing slurry 28 includes materials that contribute to the planarization process. That is, the polishing slurry may comprise certain chemical additives that will etch away or soften exposed areas of layer 18. An abrasive particulate material of a predetermined size may be included in the slurry and used to grind away portions of layer 18 in a mechanical process. Abrasive-free electrolytes (for eCMP processes), or other types of abrasive-free chemical slurries may also be used with conventional polishing pads or with fixed abrasive pads. CMP system 11 is shown as further comprising an exemplary conditioning apparatus 40 that is used to clean (“condition”) polishing pad 12 by dispensing conditioning agents 42 onto surface 30 of polishing pad 12 and removing used polishing slurry 28, wafer debris and the like (collectively referred to as “effluent”) from CMP system 11.

In accordance with the present invention, an effluent evacuation path 46 is coupled to a vacuum outlet port 48 on conditioning apparatus 40 such that a vacuum force may be applied through evacuation path 46 and used to remove the effluent from polishing pad surface 30. In most cases, effluent evacuation path 46 will comprise a hose, tube, or the like.

The evacuated effluent, in accordance with the present invention, is separated from the air stream and thereafter passed through a separator 49 to separate the used polishing slurry (referred to as “recovered polishing slurry”) from the wafer debris, conditioning fluids, etc. The recovered polishing slurry is then presented to a slurry analysis unit 50 that is used to measure the viscosity (or other parameters, perhaps) of the removed polishing slurry important to controlling the tribology of the incoming polishing slurry. A separate analysis of the chemistry of the initial effluent stream is used to determine the current “material removal rate” (MRR) associated with layer 18 (see effluent analyzer 47 in FIG. 5). The ability to determine, in real time, the material removal rate in a CMP process is well-known in the art and is used for various purposes including, for example, end point detection of the removal process.

In accordance with the present invention, the measured, current values of the MRR and polishing slurry viscosity are then used to adjust (if necessary) the viscosity and/or lubricity of the incoming polishing slurry. Referring to FIG. 5, a slurry viscosity adjustment unit 60 is shown as placed in a feedback path between slurry analysis unit 50 and slurry dispenser 42. A processor 62 is included within slurry viscosity adjustment unit 60 and receives control signals from analysis unit 50 (the measured viscosity) and effluent analyzer 47 (the material removal rate). Processor 62 compares the current values to desired values and then determines if any adjustments in slurry viscosity are required. If the viscosity of the slurry needs to be increased, a “+” control signal is sent to an “increase viscosity” reservoir 64 within slurry adjustment unit 60, which will then introduce a predetermined amount of an additive to achieve the desired, higher, viscosity. Additives of this type include, for example, soluble starch and sucrose. Similarly, if the viscosity needs to be decreased, a “−” control signal is sent to a “decrease viscosity” reservoir 66 also located within adjustment unit 60. In most cases, de-ionized water may be used as the “negative additive”. In situations where a significant slowing of the removal rate is required (i.e., a “braking” of the process), lubricants from a lubrication reservoir 70 may also be added to the slurry. A control signal from “decrease viscosity” reservoir 66 may be applied to lubrication reservoir 70 to control the addition of lubricants to the incoming polishing slurry. The particulars of the control signals are used to dictate the volume of additives supplied by the proper reservoir of additive and inserted into the slurry supply via a slurry viscosity additive supply line 68.

The process of slurry monitoring is considered on-going, with slurry analysis unit 50, effluent analyzer 47 and slurry adjustment unit 60 utilized in a continuous manner to constantly adjust/fine-tune the viscosity and/or lubricity of the polishing slurry in order to best control the material removal rate in an efficient manner.

It is to be understood that the arrangement as shown in FIG. 5 is exemplary only; there are various other systems that may be utilized to measure material removal rate or viscosity (e.g., reflectance, conductivity, torque, temperature) and create the signal inputs utilized to control the slurry adjustment unit.

While the present invention has been described with regard to the preferred embodiments, it is to be understood by those skilled in the art that the invention is not limited to these embodiments, and that changes and modifications can be made thereto without departing from the spirit and scope of the present invention as defined by the following claims.

What is claimed is:

1. A method of controlling the tribology of a chemical mechanical planarization process that utilizes a polishing slurry to planarize an irregular surface of a semiconductor wafer, the method comprising the steps of:
a) determining a current material removal rate of the irregular surface layer;
b) measuring the viscosity of the polishing slurry as it is removed from planarization process;
c) comparing the current material removal rate to a desired material removal rate; and
d) adjusting either one of the viscosity and lubricity of incoming polishing slurry if the current material removal rate is different from the desired material removal rate.

2. The method as defined in claim 1 wherein in performing step d), the viscosity of the incoming polishing slurry is increased if the current material removal rate is less than the desired material removal rate.

3. The method as defined in claim 2 where the viscosity of the incoming polishing slurry is increased by adding a material to the incoming polishing slurry selected from the group consisting of: soluble starch solution, sucrose solution, high molecular weight polymers, ethanolamine, diethanolamine, triethanol amine, and other non-reactive water soluble solvents or mixtures thereof with a viscosity substantially greater than that of deionized water.

4. The method as defined in claim 1 wherein in performing step d), the viscosity of the incoming polishing slurry is decreased if the current material removal rate is greater than the desired material removal rate.

5. The method as defined in claim 4 wherein the viscosity of the incoming polishing slurry is decreased by adding a material to the incoming polishing slurry selected from the group consisting of: 2-butanone and cyclopentanol.

6. The method as defined in claim 1 wherein in performing step d), the lubricity of the incoming polishing slurry is decreased if the current material removal rate is greater than the desired material removal rate.

7. The method as defined in claim 6 wherein the lubricity is controlled by adding a material to the incoming polishing slurry selected from the group consisting of: graphite, fatty acids and non-reactive surfactants.

8. The method as defined in claim 1 where in performing step a), a chemical analysis of the effluent is performed to determine the current material removal rate.

9. An arrangement for controlling the tribology of a polishing slurry in a chemical mechanical planarization system, the arrangement comprising
an effluent analyzer for determining a current material removal rate associated with a semiconductor wafer being processed;
a slurry analysis unit for determining the viscosity of spent slurry evacuated from the chemical mechanical planarization system; and
a slurry viscosity adjustment unit, coupled to the effluent analyzer and the slurry analysis unit for comparing the current material removal rate to a desired material removal rate and creating polishing slurry viscosity adjustments if the current rate is different from the desired rate.

10. An arrangement as defined in claim 9 wherein the slurry viscosity adjustment unit comprises
a processor for receiving the outputs from the effluent analyzer and the slurry analysis unit and generating an “increase viscosity” signal or a “decrease viscosity” signal, when necessary to match the current material removal rate to the desired material removal rate;
an increase viscosity reservoir, responsive to the “increase viscosity” signal, for dispensing a high viscosity component into the stream of the incoming polishing slurry; and
a decrease viscosity reservoir, responsive to the “decrease viscosity” signal, for dispensing a low viscosity component into the stream of the incoming polishing slurry.

11. An arrangement as defined in claim 9 further comprising a lubricant reservoir for dispensing a lubricant into the incoming polishing slurry in response to the “decrease viscosity” signal.
